(19) United States
(12) Patent Application Publication
(10) Pub. No.: US 2025/0207259 A1
(43) Pub. Date: Jun. 26, 2025

(54) ADJUSTMENT METHOD AND SUBSTRATE PROCESSING APPARATUS

(71) Applicant: Tokyo Electron Limited, Tokyo (JP)

(72) Inventor: Kiyoshi MORI, Fuchu City (JP)

(21) Appl. No.: 18/983,640

(22) Filed: Dec. 17, 2024

(30) Foreign Application Priority Data
Dec. 25, 2023 (JP) 2023-218239

(51) Int. Cl. C23C 16/52; C23C 16/458; C23C 16/46; G01B 11/02; G01B 11/24; G01B 11/26

(52) U.S. Cl. CPC C23C 16/52; C23C 16/4582; C23C 16/46; G01B 11/028; G01B 11/24; G01B 11/26

(57) ABSTRACT

A substrate processing apparatus includes: a stage having a placement surface; a processing container having a vertically-extending central axis and a cylindrical interior space in which the stage is disposed with a gap provided around the stage; a drive mechanism for moving the stage at least horizontally; and a sensor for measuring a width of the gap in a first horizontal direction intersecting the gap. An adjustment method includes: measuring widths of the gap at at least three locations on the stage by the sensor while moving the stage in a second horizontal direction perpendicular to the first horizontal direction by the drive mechanism; calculating a central position of the stage based on the widths of the gap measured at the at least three locations; and adjusting a horizontal position of the stage by the drive mechanism so that the central position of the stage is located on the central axis.

### CROSS-REFERENCE TO RELATED APPLICATION

This application is based upon and claims the benefit of priority from Japanese Patent Application No. 2023-218239, filed on Dec. 25, 2023, the entire contents of which are incorporated herein by reference.

### TECHNICAL FIELD

The present disclosure relates to an adjustment method and a substrate processing apparatus.

### BACKGROUND

Patent Document 1 below discloses a substrate processing method used for a substrate processing apparatus. The substrate processing apparatus includes a processing container, a stage disposed inside the processing container with a gap provided between the stage and an inner wall of the processing container or a side surface of a component part constituting the processing container, configured to place a substrate thereon, and configured to divide the interior of the processing container into a first space defined at an upper portion of the processing container in which substrate processing is performed on the substrate and a second space defined at a lower portion of the processing container, an exhaust mechanism configured to exhaust the first space via the gap by exhausting the second space, or configured to exhaust the first space while causing a seal gas to flow from the second space to the first space via the gap, and a drive mechanism configured to be able to move the stage. The method includes: an exhaust operation of exhausting the first space by the exhaust mechanism; and a substrate processing operation of performing the substrate processing on the substrate while changing a position of the stage by the drive mechanism to make a width of the gap uniform on a time average.

### PRIOR ART DOCUMENT

### Patent Document

Patent Document 1: Japanese Laid-Open Patent Publication No. 2023-096245

### SUMMARY

According to one embodiment of the present disclosure, there is provided an adjustment method used for a substrate processing apparatus. The substrate processing apparatus includes: a stage having a circular placement surface on which a substrate is placed; a processing container having a central axis extending in a vertical direction and a cylindrical interior space in which the stage is disposed with a gap provided around the stage; a drive mechanism configured to move the stage at least in a horizontal direction; and a sensor configured to measure a width of the gap in a first horizontal direction intersecting the gap. The adjustment method includes: a first operation of measuring widths of the gap at at least three different locations on the stage by the sensor while moving the stage in a second horizontal direction perpendicular to the first horizontal direction by the drive mechanism; a second operation of calculating a central position of the stage based on the widths of the gap measured at the at least three different locations; and a third operation of adjusting a horizontal position of the stage by the drive mechanism so that the calculated central position of the stage is located on the central axis.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a configuration of a substrate processing apparatus according to a first embodiment.

FIG. 2 is an enlarged cross-sectional view showing an example of a structure of an absorption mechanism according to the first embodiment.

FIG. 3 is a view showing an example of a gas flow during substrate processing according to the first embodiment.

FIG. 4 is a view showing another example of the gas flow during the substrate processing according to the first embodiment.

FIG. 5 is a view explaining an example of a cause of processing results according to the first embodiment becoming non-uniform.

FIG. 6 is a view explaining measurement of a gap according to the first embodiment.

FIG. 7 is a view explaining movement of a stage according to the first embodiment.

FIG. 8A is a view showing an example of a measurement result of a sensor according to the first embodiment.

FIG. 8B is a view showing another example of the measurement result by the sensor according to the first embodiment.

FIG. 9 is a view showing an example of calculation of a central position of the stage according to the first embodiment.

FIG. 10 is a view showing an example of calculation of an inclination of the stage according to the first embodiment.

FIG. 11 is a flowchart showing an example of a flow of an adjustment process according to the first embodiment.

FIG. 12 is a flowchart showing another example of the flow of the adjustment process according to the first embodiment.

FIG. 13 is a schematic cross-sectional view showing an example of a configuration of a substrate processing apparatus according to a second embodiment.

FIG. 14 is a flowchart showing an example of a flow of an adjustment process according to the second embodiment.

### DETAILED DESCRIPTION

Hereinafter, embodiments of an adjustment method and a substrate processing apparatus disclosed herein will be described in detail with reference to the drawings. The adjustment method and the substrate processing apparatus disclosed herein are not limited to the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

There is known a substrate processing apparatus having a structure in which a stage for placing a substrate thereon is disposed with a gap provided around surroundings inside a processing container. For example, Patent Document 1 discloses a structure in which a stage is provided with a gap provided around surroundings and a space around the stage is exhausted from an exhaust port while allowing a seal gas to flow via the gap. Further, Patent Document 1 discloses a structure in which a stage is provided with a gap provided around surroundings and an exhaust is performed downward from the gap.

In the substrate processing apparatus as described above, when a width of the gap in a circumferential direction of the stage is non-uniform, a gas flow may fluctuate due to the non-uniform gap in the circumferential direction of the stage, which makes substrate processing results in the circumferential direction of the stage non-uniform. For this reason, a technique for adjusting the position of the stage to make the width of the gap uniform is required for the substrate processing apparatus.

### First Embodiment

### [Configuration of Substrate Processing Apparatus]

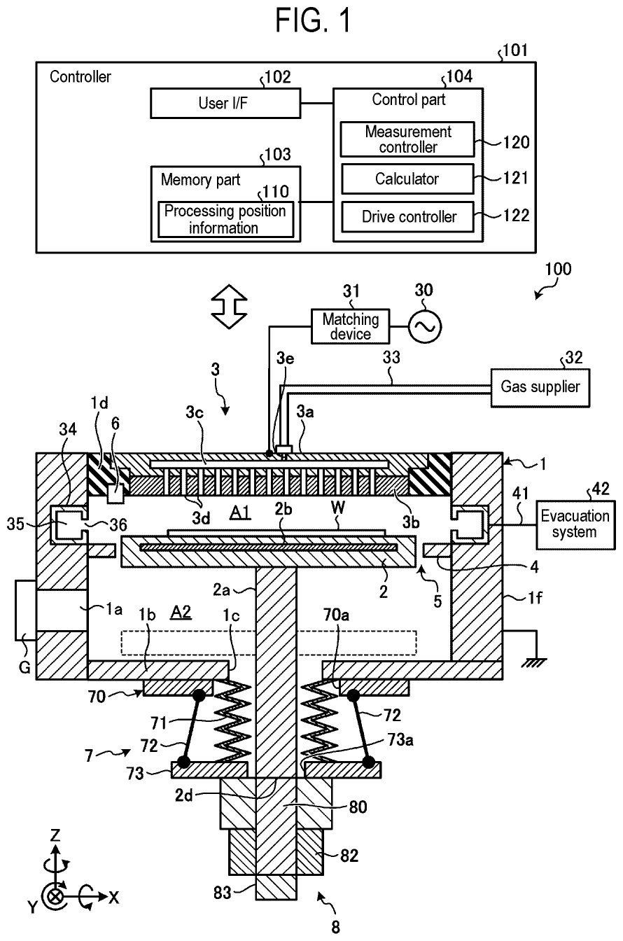

An example of a configuration of a substrate processing apparatus 100 according to a first embodiment will be described. FIG. 1 is a schematic cross-sectional view showing an example of the configuration of the substrate processing apparatus 100 according to the first embodiment. The substrate processing apparatus 100 is an apparatus that performs substrate processing on a substrate. In the following, a case where the substrate processing apparatus 100 is a film forming apparatus and a film forming process as the substrate processing is performed by the substrate processing apparatus 100 will be mainly described as an example. The substrate processing apparatus 100 performs a plasma-based CVD (Chemical Vapor Deposition) processing on a substrate W.

The substrate processing apparatus 100 includes a processing container 1. For example, the processing container 1 is formed in a substantially cylindrical shape and is made of metal such as aluminum or nickel whose surface is anodized. The processing container 1 includes a bottom wall 1b and a sidewall if. The processing container 1 is grounded. The processing container 1 is configured to be hermetically sealed such that an interior thereof is kept in a vacuum atmosphere.

A stage 2 is provided inside the processing container 1. The stage 2 is formed in a substantially flat cylindrical shape and is made of, for example, metal such as aluminum or nickel, or aluminum nitride (AlN) with a metal mesh electrode embedded therein. That is, the stage 2 has a circular placement surface. The substrate W to be processed, such as a semiconductor wafer, is placed on an upper surface of the stage 2. The stage 2 also functions as a lower electrode. A support member 2a is connected to the center of a lower surface of the stage 2. The stage 2 is supported from below by the support member 2a. The support member 2a is formed in a substantially cylindrical shape. An opening 1c is formed in a bottom wall 1b of the processing container 1 at a position below the stage 2 and corresponding to the support member 2a. The opening 1c is formed to have a diameter larger than that of the support member 2a. The support member 2a extends downward from the stage 2 and penetrates the opening 1c of the bottom wall 1b of the processing container 1. In this embodiment, the stage 2 corresponds to a stage of the present disclosure.

The stage 2 includes a built-in heater 2b. The heater 2b generates heat in response to power supplied from outside the processing container 1, and heats the substrate W placed on the stage 2. Although not shown, a flow path supplied with a coolant whose temperature is controlled by a chiller unit provided outside the processing container 1 is formed inside the stage 2. The stage 2 may control the substrate W to have a predetermined temperature through the heating by the heater 2b and the cooling by the coolant supplied from the chiller unit. The stage 2 may control the temperature of the substrate W through the heating by the heater 2b without the flow path. The stage 2 may control the temperature of the substrate W by the coolant supplied from the chiller unit without the heater 2b.

Although not shown, an electrode that generates an electrostatic force by an externally-supplied voltage is embedded in the stage 2. The electrostatic force generated by the electrode attracts and holds the substrate W on the upper surface of the stage 2. Although not shown, the stage 2 is provided with lift pins for delivering the substrate W between the stage 2 and a transfer mechanism (not shown) provided outside the processing container 1.

A shower head 3 is provided above the stage 2. The shower head 3 is formed in a substantially circular plate shape and made of a conductive metal such as aluminum or nickel. A space between the lower surface of the shower head 3 and the upper surface of the stage 2 is a processing space A1 where a film formation process is performed. The shower head 3 is supported on the upper portion of the stage 2 via an insulating member 1d such as ceramics or the like. This electrically insulates the processing container 1 and the shower head 3 from each other. The shower head 3 constitutes a ceiling portion of the processing container 1.

The shower head 3 includes a top plate 3a and a shower plate 3b. The top plate 3a is provided so as to close the interior of the processing container 1 from above. The shower plate 3b is provided below the top plate 3a so as to face the stage 2. A gas diffusion chamber 3c is formed in the top plate 3a. A plurality of gas discharge holes 3d in communication with the gas diffusion chamber 3c are formed in the top plate 3a and the shower plate 3b.

The top plate 3a is formed with a gas introduction port 3e through which a gas is introduced into the gas diffusion chamber 3c. A gas supplier 32 is connected to the gas introduction port 3e via a pipe 33. The gas supplier 32 includes gas sources of various gases used in the film formation process and gas supply lines connected to the respective gas sources. Each gas supply line is provided with control devices for controlling a flow of a gas, such as a valve and a flow rate controller. The gas supplier 32 controls a flow rate of the gas by the control devices provided in each gas supply line and supplies various gases to the shower head 3 via the pipe 33. The gas supplied to the shower head 3 diffuses inside the gas diffusion chamber 3c and is discharged from each gas discharge hole 3d into the processing space A1 below the shower head 3.

The shower plate 3b is paired with the stage 2 and also functions as an electrode plate for forming capacitively coupled plasma (CCP) in the processing space A1. A radio-frequency (RF) power supply 30 is connected to the shower head 3 via a matching device 31. The RF power supply 30 supplies RF power to the shower head 3 via the matching device 31. The RF power supplied from the RF power supply 30 to the shower head 3 is supplied from a lower surface of the shower head 3 into the processing space A1. The gas supplied into the processing space A1 is plasmarized by the RF power supplied into the processing space A1. The RF power supply 30 may supply RF power to the stage 2 instead of the shower head 3. In this case, the shower head 3 is grounded. The RF power supply 30 may supply RF power of different frequencies and magnitudes to both the stage 2 and the shower head 3.

A lower end portion 2d of the support member 2a supporting the stage 2 is located outside the processing container 1 and is connected to a rotation mechanism 8. The rotation mechanism 8 includes a rotary shaft 80, a vacuum seal 81, and a motor 82. The lower end portion 2d of the support member 2a is connected to an upper end of the rotary shaft 80. The rotary shaft 80 rotates integrally with the support member 2a about an axis passing through the center of the stage 2. A slip ring 83 is provided at a lower end of the rotary shaft 80. The slip ring 83 includes an electrode and is electrically connected to various wirings for supplying power to inner components of the stage 2. For example, the slip ring 83 is electrically connected to wirings for supplying power to the heater 2b embedded in the stage 2. In addition, for example, the slip ring 83 is electrically connected to a wiring for applying a voltage to an electrode for electrostatically attracting the substrate W onto the stage 2.

The motor 82 rotates the rotary shaft 80. With the rotation of the rotary shaft 80, the stage 2 is rotated via the support member 2a. When the rotary shaft 80 rotates, the slip ring 83 also rotates together with the rotary shaft 80. In this case, the electrical connection between the slip ring 83 and the wiring is maintained.

The vacuum seal 81 is, for example, a magnetic fluid seal. The vacuum seal 81 is provided around the rotary shaft 80. The vacuum seal 81 hermetically seals the rotary shaft 80 while maintaining smooth rotation of the rotary shaft 80.

The substrate processing apparatus 100 includes a drive mechanism 7. The drive mechanism 7 is configured to move the stage 2. The lower end portion 2d of the support member 2a is connected to the drive mechanism 7 via the vacuum seal 81. The drive mechanism 7 includes an absorbing mechanism 70, a bellows 71, a plurality of (e.g., six) actuators 72, and a base member 73.

The bellows 71 is provided so as to surround the periphery of the support member 2a. An upper end of the bellows 71 passes through an opening 70a formed in the absorbing mechanism 70 and is connected to the bottom wall 1b of the processing container 1. A lower end of the bellows 71 is connected to the base member 73. Thus, the bellows 71 airtightly seals a space between the bottom wall 1b of the processing container 1 and the base member 73. The bellows 71 is extendible as the base member 73 moves.

The base member 73 is formed with an opening 73a having a diameter larger than that of the lower end portion 2d of the support member 2a. The support member 2a passes through the opening 73a, and the lower end portion 2d of the support member 2a is connected to the rotary shaft 80. The vacuum seal 81 is provided around the rotary shaft 80 connected to the lower end portion 2d of the support member 2a. The base member 73 is fixed to an upper surface of the vacuum seal 81. As a result, the base member 73 is connected to the stage 2 via the vacuum seal 81, the rotary shaft 80, and the support member 2a, and may move integrally with the stage 2.

The actuators 72 are arranged in parallel to one another between the bottom wall 1b of the processing container 1 and the base member 73. The actuators 72 are extendible, are rotatably and slidably connected to the base member 73 via universal joints, and are rotatably and slidably connected to the bottom wall 1b of the processing container via universal joints.

The actuators 72 and the base member 73 constitute a parallel link mechanism capable of moving and tilting the stage 2 in any direction. For example, FIG. 1 shows an X-axis direction, a Y-axis direction, and a Z-axis direction. The Z-axis direction is a vertical direction. The X-axis direction and the Y-axis direction are two horizontal directions perpendicular to each other. The actuators 72 and the base member 73 constitute a parallel link mechanism capable of moving the base member 73, for example, in the directions of the X-axis direction, the Y-axis direction, and the Z-axis direction shown in FIG. 1, and in the directions of rotation around the X-axis direction, the Y-axis direction, and the Z-axis direction. A movement coordinate system of the parallel link mechanism constituted by the actuators 72 and the base member 73 is adjusted in advance to coincide with a coordinate system of the processing container 1. The parallel link mechanism connects the bottom wall 1b of the processing container 1 and the base member 73, so that the actuators 72 may move the base member 73 relative to the bottom wall 1b of the processing container 1. This makes it possible to adjust a position and inclination of the stage 2. For example, the actuators 72 may adjust a vertical position of the stage 2 by moving the base member 73 in the vertical direction (Z-axis direction). In addition, for example, the actuators 72 may adjust a horizontal position of the stage 2 by moving the base member 73 in the horizontal direction (X-axis direction and Y-axis direction). Further, for example, the actuators 72 may adjust the inclination of the stage 2 by tilting the base member 73 with respect to the bottom wall 1b. In addition, the actuators 72 may raise and lower the stage 2 by raising and lowering the base member 73.

The stage 2 is configured to be movable vertically between a processing position and a transfer position by the drive mechanism 7. FIG. 1 shows the stage 2 located at the processing position. The transfer position is indicated by a dashed line. The processing position is a position at which the substrate processing (e.g., the film formation process) is performed. The transfer position is a position at which the substrate W is transferred between the processing container 1 and the outside.

An opening 1a for loading and unloading the substrate W therethrough is formed in the sidewall if of the processing container 1 at a height corresponding to the transfer position. The opening 1a is opened and closed by a gate valve G.

When loading and unloading the substrate W, the stage 2 is lowered to the transfer position by the drive mechanism 7, and the gate valve G is opened. The substrate W is loaded into the processing container 1 via the opening 1a by a transfer mechanism such as a transfer arm, and is placed on the stage 2. On the other hand, when the substrate processing is performed on the substrate W, the drive mechanism 7 raises the stage 2 to the processing position.

A ring-shaped component member 4 is provided on the sidewall if of the processing container 1 at a height corresponding to the processing position of the stage 2. The component member 4 has a cylindrical opening with a diameter slightly larger than that of the stage 2. The component member 4 is disposed so that the stage 2 raised to the processing position is positioned inside the opening, and so that the component member 4 surrounds the periphery of the stage 2 with a gap 5 provided between the component member 4 and the side surface of the stage 2.

When the stage 2 is raised to the processing position, the interior of the processing container 1 is divided into an upper processing space A1 where the substrate processing is performed on the substrate W, and a lower space A2.

The absorbing mechanism 70 includes an opening 70a in communication with the interior of the processing container 1 via the opening 1c in the bottom wall 1b of the processing container 1. The actuators 72 are connected to the absorbing mechanism 70 without being connected to the bottom wall 1b of the processing container 1. As a result, even if the bottom wall 1b of the processing container 1 is deformed, stress caused by the deformation of the bottom wall 1b of the processing container 1 is absorbed by the absorbing mechanism 70. Therefore, the stress caused by the deformation of the bottom wall 1b of the processing container 1 is not transmitted to the actuators 72, and the adjustment accuracy of the position and inclination of the stage 2 may be suppressed from being degraded.

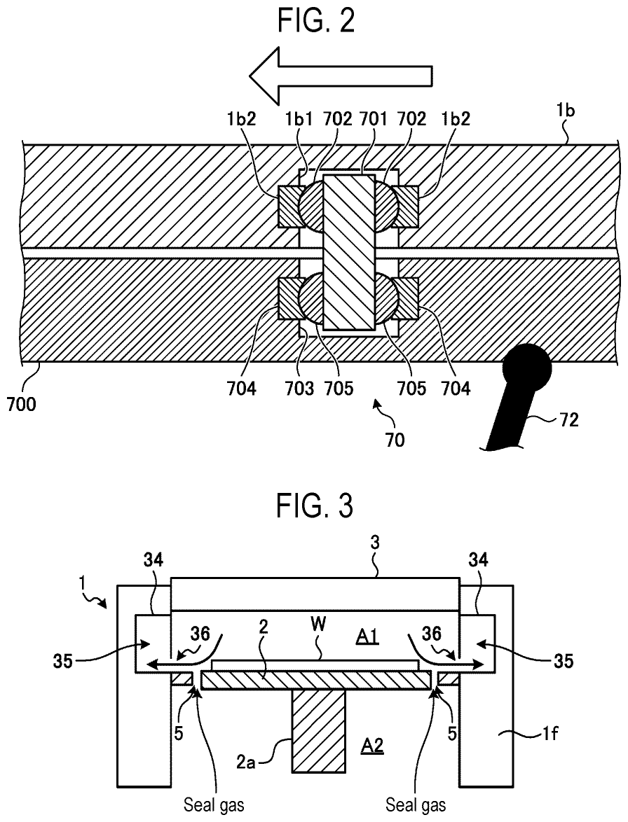

The absorbing mechanism 70 is provided on the bottom wall 1b of the processing container 1 to absorb the deformation of the bottom wall 1b of the processing container 1. FIG. 2 is an enlarged cross-sectional view showing an example of a structure of the absorbing mechanism 70 according to the first embodiment. The absorbing mechanism 70 includes a plate member 700 and a link member 701.

The plate member 700 is formed in a plate annular shape, and is disposed below the bottom wall 1b of the processing container 1. The plate member 700 is disposed at a distance from the bottom wall 1b of the processing container 1 in order to block the radiation of heat and vibration from the processing container 1.

The link member 701 includes one end rotatably and slidably connected to the bottom wall 1b of the processing container 1, and the other end rotatably and slidably connected to the plate member 700. For example, as shown in FIG. 2, a recess 1b1 is formed in the bottom wall 1b of the processing container 1, and a spherical bearing 1b2 is provided in the recess 1b1. A spherical convex portion 702 is formed at one end of the link member 701. The convex portion 702 is connected to the spherical bearing 1b2, so that the link member 701 is rotatably and slidably connected to the bottom wall 1b of the processing container 1 via the convex portion 702 and the spherical bearing 1b2. Meanwhile, a recess 703 is formed in the upper surface of the plate member 700 at a position corresponding to the recess 1b1 of the processing container 1. A spherical bearing 704 is provided in the recess 703. A spherical convex portion 705 is formed at the other end of the link member 701. By connecting the convex portion 705 to the spherical bearing 704, the link member 701 is connected to the plate member 700 via the convex portion 705 and the spherical bearing 704 so as to be rotatable and slidable.

The link member 701 rotates in a direction according to the deformation of the bottom wall 1b of the processing container 1, thereby suppressing the transmission of the deformation to the plate member 700. For example, when the bottom wall 1b of the processing container 1 is deformed in the direction of the arrow in FIG. 2, the link member 701 receives the stress caused by the deformation of the bottom wall 1b. By rotating together with the bottom wall 1b in the direction of the arrow in FIG. 2, the link member 701 suppresses the transmission of the stress caused by the deformation of the bottom wall 1b to the plate member 700. The actuators 72 are connected to the plate member 700. As a result, the stress caused by the deformation of the bottom wall 1b of the processing container 1 is not transmitted to the actuators 72 via the plate member 700, which makes it possible to suppress a decrease in the adjustment accuracy of the position and inclination of the stage 2.

A plurality of link members 701 are arranged along an extension direction of the plate member 700. In this embodiment, for example, three link members 701 are provided at approximately equal intervals along the extension direction of the plate member 700. Four or more link members 701 may be provided at approximately equal intervals along the extension direction of the plate member 700.

Returning to FIG. 1, the processing container 1 is provided with an exhaust guide member 34 on the sidewall if around the processing space A1 so as to surround the processing space A1. The guide member 34 includes an internal flow passage 35 having, for example, a rectangular vertical cross section and an annular shape in a plan view. The guide member 34 includes a slit-shaped exhaust port 36 which is formed along the circumferential direction and is open toward the processing space A1.

An exhaust system 42 is connected to the flow passage 35 of the guide member 34 via a pipe 41. The exhaust system 42 may include a pressure adjustment valve and a vacuum pump. When exhaust is performed by the exhaust system 42, the gas supplied to the processing space A1 flows from the slit-shaped exhaust port 36 of the guide member 34 to the flow passage 35 and is exhausted from the pipe 41 to the exhaust system 42. An internal pressure of the processing space A1 is adjusted by the pressure adjustment valve. The interior of the processing container 1 may be depressurized by the exhaust system 42 to a predetermined degree of vacuum suitable for the film formation process.

Further, the substrate processing apparatus 100 according to the embodiment includes a sensor 6. The sensor 6 is configured to be capable of measuring a width of the gap 5 between the stage 2 and the processing container 1. For example, the sensor 6 is configured as a two-dimensional sensor that may measure a shape (profile) by irradiating a laser and detecting a reflected laser thereof. The sensor 6 measures a shape including the gap 5 and a peripheral edge of the stage 2. The sensor 6 is provided at a position where the gap 5 may be measured. For example, the sensor 6 is provided in the ceiling portion above the gap 5 inside the processing container 1. In this embodiment, the sensor 6 is provided in an insulating member 1d above the gap 5. The sensor 6 measures the gap 5.

The substrate processing apparatus 100 includes a controller 101. The controller 101 is, for example, a computer, and controls individual parts of the substrate processing apparatus 100. The operation of the substrate processing apparatus 100 is generally controlled by the controller 101. The controller 101 includes a user I/F (interface) 102, a memory part 103, and a control part 104.

The user I/F 102 is constituted with a keyboard through which a processing manager inputs commands to manage the substrate processing apparatus 100, a display that visually displays an operational status of the substrate processing apparatus 100, and the like.

The memory part 103 stores a control program (software) and various programs for implementing various processes executed in the substrate processing apparatus 100 under the control of the control part 104. The memory part 103 also stores various data used in the programs executed by the control part 104. For example, the memory part 103 stores a recipe incorporating processing condition data and the like, and processing position information 110. The processing position information 110 is data incorporating the position and inclination of the stage 2 at the processing position. The programs and data may be stored in a non-transitory computer-readable recording medium (e.g., a hard disk, an optical disk such as a DVD, a flexible disk, a semiconductor memory, etc.). The programs and data may also be transmitted from another device at any time via a dedicated line and may be used in an online environment.

The control part 104 includes a CPU (Central Processing Unit) and a memory, and controls individual parts of the substrate processing apparatus 100. The control part 104 reads out the control program stored in the memory part 103, and executes the process of the control program thus read. The control part 104 functions as various processors by the operation of the control program. For example, the control part 104 includes functions of a measurement controller 120, a calculator 121, and a drive controller 122. In this embodiment, a case where the control part 104 includes the functions of the measurement controller 120, the calculator 121, and the drive controller 122 will be described. However, the functions of the measurement controller 120, the calculator 121, and the drive controller 122 may be distributed and implemented by a plurality of controllers. For example, the measurement controller 120, the calculator 121, and the drive controller 122 may be distributed and implemented by different controllers capable of communicating data with respect to each other.

The measurement controller 120 and the calculator 121 will be described in detail later.

The drive controller 122 performs various controls to drive the stage 2. For example, the drive controller 122 controls the drive mechanism 7 to control the position and angle of the stage 2. The drive controller 122 also controls the rotation mechanism 8 to control the rotation of the stage 2. In this embodiment, the drive controller 122 corresponds to an adjuster of the present disclosure.

Next, a flow of the film formation process performed on the substrate W by the substrate processing apparatus 100 according to the embodiment will be briefly described.

When the substrate W is loaded, the gate valve G is opened. The drive controller 122 controls the drive mechanism 7 to lower the stage 2 to a delivery position. The substrate W is loaded into the processing container 1 via the opening 1a by a transfer mechanism such as a transfer arm or the like, and is placed on the stage 2. The drive controller 122 controls the drive mechanism 7 to raise the stage 2 to the processing position.

The control part 104 controls the stage 2 to have a predetermined temperature suitable for the film formation process. For example, the control part 104 controls a heater power supply (not shown) connected to the heater 2b, and supplies power from the heater power supply to the heater 2b such that the heater 2b generates heat. The control part 104 also controls a chiller unit to circulate a coolant inside the stage 2. The control part 104 controls the stage 2 to have the predetermined temperature suitable for the film formation process through the heating by the heater 2b and the cooling by the coolant supplied from the chiller unit. The control part 104 also controls the exhaust system 42 to reduce the internal pressure of the processing container 1 to the predetermined degree of vacuum suitable for the film formation process by the exhaust system 42.

Further, the control part 104 performs the film formation process on the substrate W. The control part 104 controls the gas supplier 32 to supply various gases used in the film formation process from the gas supplier 32 and to introduce various gases into the processing space A1 from the shower head 3. The control part 104 also rotates the stage 2 by the rotation mechanism 8. For example, the drive controller 122 controls the rotation mechanism 8 to rotate the stage 2 about the support member 2a supporting the stage 2 as a rotation axis. The control part 104 controls the RF power supply 30 to supply radio-frequency power from the RF power supply 30 to generate plasma in the processing space A1 and to perform the film formation process on the substrate W. The control part 104 may rotate the stage 2 as necessary. Further, the control part 104 may perform the film formation process on the substrate W in a state in which the stage 2 is stopped without being rotated.

FIG. 3 is a view showing an example of a gas flow during the substrate processing according to the first embodiment. FIG. 3 shows an example of the gas flow in the processing space A1 inside the processing container 1 when the film formation process is performed as the substrate processing.

The stage 2 on which the substrate W is placed is disposed inside the processing container 1, and the shower head 3 is disposed to face the stage 2. The processing space A1 is formed between the stage 2 and the shower head 3. When the stage 2 is moved to the processing position by the drive mechanism 7, the interior of the processing container 1 is divided into the upper processing space A1 and the lower space A2 by the stage 2.

When exhaust is performed by the exhaust system 42, the gas supplied to the processing space A1 flows from the exhaust port 36 of the guide member 34 to the flow passage 35, and is exhausted from the pipe 41 to the exhaust system 42. The substrate processing apparatus 100 according to the embodiment is capable of supplying a seal gas to the lower space A2 via a gas supply pipe (not shown). As the seal gas, for example, an inert gas such as a nitrogen (N₂) gas may be used. A source of the seal gas supplied to the lower space A2 may be the gas supplier 32 or a separate gas supply system.

When performing the film formation process, the substrate processing apparatus 100 supplies the seal gas to the lower space A2 such that the seal gas flows from the lower space A2 to the processing space A1 via the gap 5. Further, the substrate processing apparatus 100 controls the exhaust system 42 to exhaust the processing space A1 from around the stage 2 using the guide member 34. Subsequently, the substrate processing apparatus 100 supplies various gases used in the film formation process from the shower head 3 to the processing space A1. This makes it possible to prevent the gas supplied from the shower head 3 to the processing space A1 from flowing into the lower space A2 via the gap 5.

In the present embodiment, the substrate processing apparatus 100 is configured to exhaust the processing space A1 from the surroundings of the stage 2 while allowing the seal gas to flow from the lower space A2 to the processing space A1 via the gap 5. However, the present disclosure is not limited thereto. The substrate processing apparatus 100 may be configured to exhaust the processing space A1 via the gap 5 by exhausting the lower space A2 of the processing container 1.

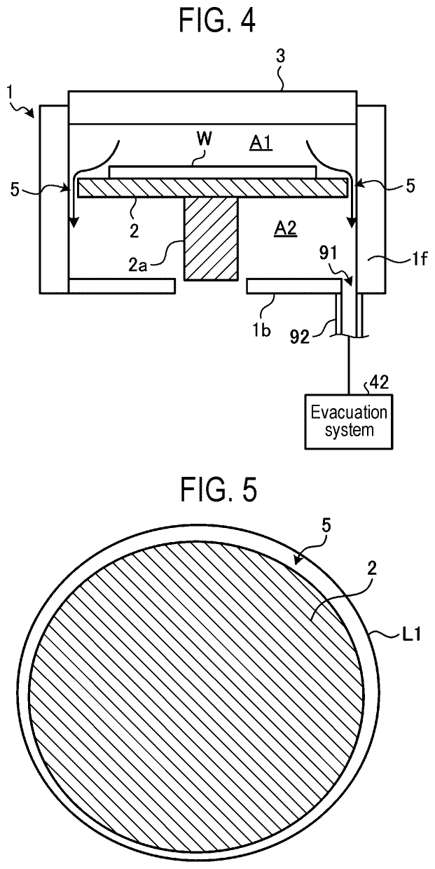

FIG. 4 is a view showing another example of the gas flow during the substrate processing according to the first embodiment. FIG. 4 shows the gas flow in the case where the substrate processing apparatus 100 is configured to exhaust the processing space A1 via the gap 5 by exhausting the lower space A2 of the processing container 1.

The stage 2 on which the substrate W is placed is disposed inside the processing container 1, and the shower head 3 is disposed to face the stage 2. The processing space A1 is formed between the stage 2 and the shower head 3. When the stage 2 is moved to the processing position by the drive mechanism 7, the interior of the processing container 1 is divided into the upper processing space A1 and the lower space A2 by the stage 2.

The gap 5 is provided between the stage 2 and the inner wall of the processing container 1. For example, the inner wall of the processing container 1 surrounds the stage 2 located at the processing position with the gap 5 provided therebetween.

The processing container 1 includes an exhaust port 91 formed in the bottom wall 1b. The exhaust port 91 is connected to the exhaust system 42 via an exhaust pipe 92. In the processing container 1 shown in FIG. 4, the processing space A1 may be exhausted via the gap 5 by exhausting the lower space A2 from the exhaust port 91 using the exhaust system 42.

When the substrate processing apparatus 100 having the configuration shown in FIG. 4 performs the film formation process, the exhaust system 42 exhausts the lower space A2 from the exhaust port 91, thereby exhausting the processing space A1 via the gap 5. The substrate processing apparatus 100 supplies various gases used for the film formation process from the shower head 3 to the processing space A1.

In the substrate processing apparatus 100, when the width of the gap 5 is non-uniform in the circumferential direction of the stage 2, the gap 5 may cause a bias in the gas flow in the circumferential direction of the stage 2. As a result, the processing results of the film formation process may become non-uniform in the circumferential direction of the stage 2. For example, in the case in which the substrate processing apparatus 100 includes the exhaust path as shown in FIGS. 3 and 4, when the width of the gap 5 is non-uniform in the circumferential direction of the stage 2, exhaust characteristics may become non-uniform in the circumferential direction of the stage 2. This may cause the bias in the gas flow. As a result, the processing results of the film formation process may become non-uniform in the circumferential direction of the stage 2.

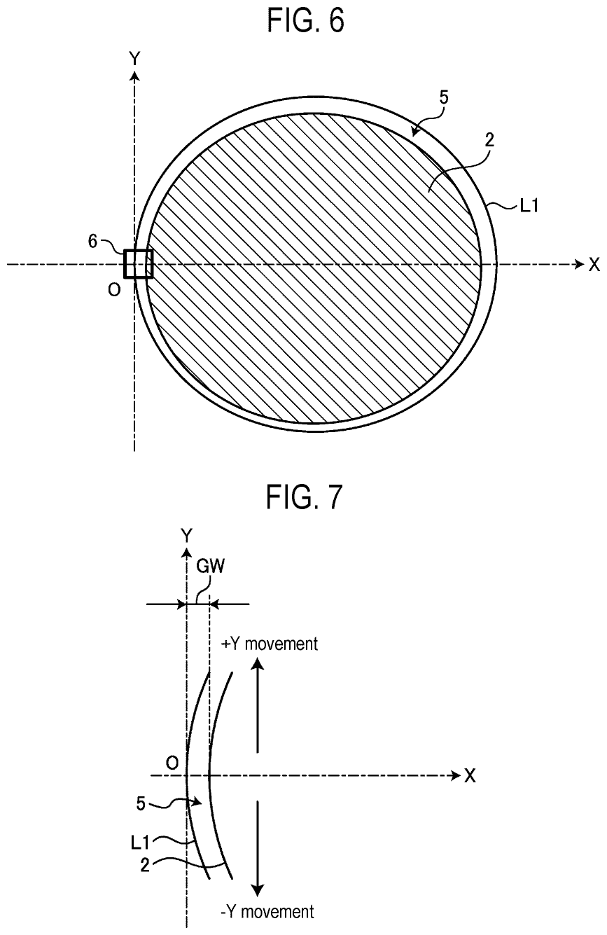

FIG. 5 is a view for explaining an example of a cause of the processing results according to the first embodiment becoming non-uniform. FIG. 5 shows a top view of the stage 2 as seen from above. The stage 2 has a circular upper surface. The substrate W is placed on the upper surface of the stage 2. In FIG. 5, a cylindrical space in which the stage 2 may be placed is indicated by a circular line L1 at the processing position in the interior of the processing container 1. The stage 2 is placed with the gap 5 provided between the stage 2 and the line L1. In the case of the configuration shown in FIG. 3, the line L1 indicates the inner surface of the ring-shaped component member 4. The gap 5 is formed between the inner surface of the component member 4 and the stage 2, so that the seal gas flows through the gap 5. In the case of the configuration shown in FIG. 4, the line L1 is the inner surface of the processing container 1. The gap 5 is formed between the inner surface of the processing container 1 and the stage 2, so that the exhaust gas flows through the gap 5. In this case, when the position of the stage 2 is slightly shifted as shown in FIG. 5, a clearance of the gap 5 becomes non-uniform in the circumferential direction. When the clearance of the gap 5 is not uniform in the circumferential direction, the gas flow is biased in the circumferential direction on the upper surface of the stage 2, which makes the film formation difficult to become uniform. For example, in the case of the configuration shown in FIG. 3, the flow of the seal gas is large in a portion having a relatively large clearance and the flow of the seal gas is small in a portion having a relatively small clearance. As a result, the gas flow is biased on the upper surface of the stage 2, making the film formation difficult to become uniform in the circumferential direction. Further, in the case of the configuration shown in FIG. 4, the exhaust flow is large in a portion having a relatively large clearance and the exhaust flow is small in a portion having a relatively small clearance. As a result, the gas flow is biased on the upper surface of the stage 2, making the film formation difficult to become uniform in the circumferential direction.

There are various factors that make the width of the gap 5 non-uniform in the circumferential direction of the stage 2. For example, the stage 2 may be heated to a high temperature due to the heat generated by the heater 2b and the heat generated from plasma during the film formation process. For example, the stage 2 may be heated to 500 degrees C. or higher during the film formation process. The diameter of the stage 2 may be changed due to thermal expansion caused by the high temperature. In addition, since the stage 2 is manufactured by combining many parts, there is some variation in diameter for each stage 2 due to a manufacturing error or the like.

In contrast, the sidewall if and the component member 4 of the processing container 1 may not be heated to a high temperature as in the stage 2 during the film formation process. Thus, the sidewall if and the component member 4 may be less susceptible to the thermal expansion. Further, since the sidewall if and the component member 4 of the processing container 1 are manufactured by combining a single or a small number of members, the manufacturing error is small. Therefore, the sidewall if and the component member 4 of the processing container 1 may be changed little in size, and therefore the diameter of the opening may be considered to be constant.

As described above, there may occur a state in which the clearance of the gap 5 is not uniform in the circumferential direction due to the dimensional change caused by thermal expansion or a misalignment between the central position of the processing container 1 and the central position of the stage 2. Therefore, the substrate processing apparatus 100 according to the embodiment performs teaching to adjust the position of the stage 2 as follows.

The measurement controller 120 controls the temperature of the stage 2 to a target temperature for adjusting the position of the stage 2. For example, when adjusting the position of the stage 2 in conformity with the film formation process, the measurement controller 120 controls the heater power supply (not shown) connected to the heater 2b to supply power to the heater 2b so that the heater 2b generates heat. Thus, the temperature of the stage 2 is controlled to the temperature during the film formation process.

FIG. 6 is a view for explaining the measurement of the gap 5 according to the first embodiment. FIG. 6 shows a top view of the stage 2 as seen from above. The stage 2 has a circular upper surface. Further, in FIG. 6, a cylindrical space in which the stage 2 is placed at the processing position in the interior of the processing container 1 is indicated by a circular line L1. In the case of the configuration shown in FIG. 3, the line L1 indicates the inner surface of the ring-shaped component member 4. Further, in the case of the configuration shown in FIG. 4, the line L1 is the inner surface of the processing container 1. In addition, the position of the sensor 6 provided above the stage 2 is shown in FIG. 6.

The sensor 6 is configured to measure the width of the gap 5 in a first horizontal direction intersecting the gap 5. For example, the sensor 6 measures the width of the gap 5 by setting the central direction toward the center of the line L1 as the first horizontal direction. The measurement controller 120 measures widths of the gap 5 at at least three different locations on the stage 2 by the sensor 6 while moving the stage 2 by the drive mechanism 7 in a second horizontal direction perpendicular to the first horizontal direction.

In the following description, a coordinate system is used in which a position on the line L1 where the sensor 6 measures the width of the gap 5 is defined as an origin O in the horizontal plane, the first horizontal direction is defined as the X-axis direction, the second horizontal direction is defined as the Y-axis direction, and the vertical direction is defined as the Z-axis direction.

In FIG. 6, the position on the line L1 where the sensor 6 measures the width of the gap 5 is defined as the origin O on the horizontal plane, the first horizontal direction in which the sensor 6 measures the width of the gap 5 is defined as the X-axis direction, and the second horizontal direction perpendicular to the first horizontal direction is defined as the Y-axis direction.

The measurement controller 120 controls the sensor 6 and the drive mechanism 7 such that the sensor 6 measures the width of the gap 5 at at least three different locations on the stage 2 while moving the stage 2 in the Y-axis direction by the drive mechanism 7. FIG. 7 is a view for explaining the movement of the stage 2 according to the first embodiment. For example, the measurement controller 120 moves the stage 2 in both a positive Y-axis direction and a negative Y-axis direction, or in either the positive Y-axis direction or the negative Y-axis direction, and measures widths GW of the gap 5 at at least three different locations. For example, as a result of moving the stage 2 in the positive Y-axis direction and measuring the width GW of the gap 5, the width GW of the gap 5 becomes wider at the second location than at the first location. At this time, when the stage 2 is further moved in the positive Y-axis direction, the stage 2 may be brought into contact with the component member 4 or the inner surface of the processing container 1. Therefore, in a case in which the width GW of the gap 5 is measured by the sensor 6 by moving the stage 2 to one side in the Y-axis direction, when the width GW of the gap 5 is gradually wider, the measurement controller 120 moves the stage 2 to the other side in the Y-axis direction and measures the width GW of the gap 5 using the sensor 6. For example, as a result of moving the stage 2 in the positive Y-axis direction and measuring the width GW of the gap 5, when the width GW of the gap 5 becomes wider at the second location than at the first location, the measurement controller 120 moves the stage 2 in the negative Y-axis direction and measures the width GW of the gap 5 at the third point using the sensor 6.

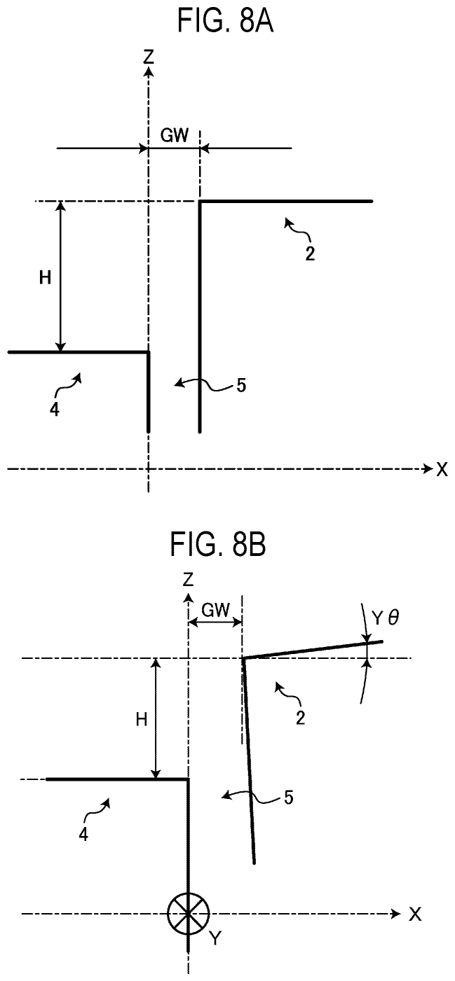

The sensor 6, which is a two-dimensional sensor, measures a shape including the gap 5 and the peripheral edge of the stage 2 at individual measurement locations. FIG. 8A is a view showing an example of the measurement result by the sensor 6 according to the first embodiment. FIG. 8A shows a shape in the configuration in which the ring-shaped component member 4 shown in FIG. 3 is provided. In FIG. 8A, a line indicating the shape measured by the sensor 6 is shown. In FIG. 8A, reference numerals are denoted to portions corresponding to the stage 2, the component member 4, and the gap 5, respectively.

The measurement controller 120 measures the width of the gap 5 from the shape measured by the sensor 6. For example, the measurement controller 120 measures a width of a portion where there is no line indicating the shape, as the width GW of the gap 5.

Since the shape measured by the sensor 6 includes the peripheral edge of the stage 2, a height of the stage 2 in the Z-axis direction may be measured. The measurement controller 120 measures the height of the stage 2 in the Z-axis direction from the shape measured by the sensor 6. For example, the measurement controller 120 measures the height of the stage 2 in the Z-axis direction at a predetermined position as a reference. For example, when the shape includes the component member 4, the measurement controller 120 measures the height H of the stage 2 in the Z-axis direction using the upper surface of the component member 4 as a reference plane. Alternatively, the measurement controller 120 may measure a height of the stage 2 in the Z-axis direction at a position of the peripheral edge of the stage 2 in the Z-axis direction in the shape measured by the sensor 6, instead of the height H using the upper surface of the component member 4 as a reference plane. Further, the measurement controller 120 may measure a height of the stage 2 in the Z-axis direction at a position of an edge of the upper surface of the stage 2 in the Z-axis direction.

Further, since the shape measured by the sensor 6 includes the peripheral edge of the stage 2, the inclination of the upper surface of the stage 2 may be measured. FIG. 8B is a view showing another example of the measurement result by the sensor 6 according to the first embodiment. FIG. 8B shows a shape in the configuration in which the ring-shaped component member 4 shown in FIG. 3 is provided. FIG. 8B shows the measurement result by the sensor 6 when the stage 2 is tilted. The measurement controller 120 measures the inclination of the upper surface of the stage 2 from the shape measured by the sensor 6. For example, the measurement controller 120 measures a rotational angle Yθ of the stage 2 about the Y-axis direction of the stage 2 as the rotation axis.

The measurement controller 120 measures the width of the gap 5 at at least three different locations on the stage 2 using the sensor 6 while moving the stage 2 in the Y-axis direction. Further, the measurement controller 120 also measures the height of the stage 2 in the Z-axis direction at at least two of the at least three different locations where the width of the gap 5 is measured. For example, the measurement controller 120 measures the height of the stage 2 in the Z-axis direction at each location where the width of the gap 5 is measured. Further, the measurement controller 120 measures the rotational angle Yθ of the stage 2 about the Y-axis direction as the rotation axis at at least one of the at least three different locations where the width of the gap 5 is measured.

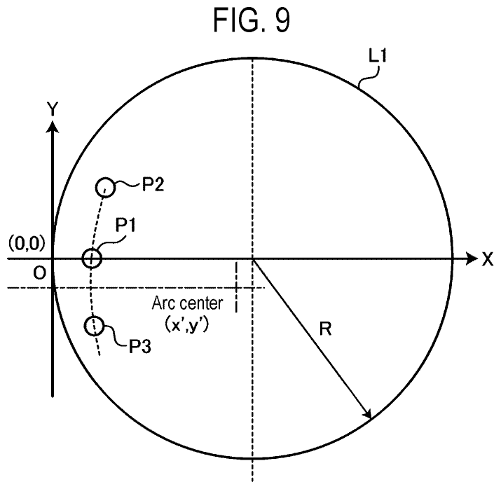

The calculator 121 calculates a central position of the stage 2 from the widths of the gaps 5 measured at at least three different locations. FIG. 9 is a view showing an example in which the central position of the stage 2 is calculated according to the first embodiment. In FIG. 9, three measurement locations where the gap 5 is measured are denoted as measurement locations P1 to P3 on a horizontal plane in the X-axis direction and the Y-axis direction. In addition, in FIG. 9, a cylindrical space in which the stage 2 may be placed at the processing position in the interior of the processing container 1 is indicated by a circular line L1. The sidewall if and the component member 4 of the processing container 1 have small dimensional errors and changes, and the diameter of the opening may be considered to be constant. The line L1 may be expressed as a circle having a radius R whose center is located on the X-axis. The radius R of the line L1 is half the diameter of the opening and is determined from design data of the sidewall if and the component member 4 of the processing container 1.

The calculator 121 calculates coordinates of the measurement locations P1 to P3 in the horizontal plane from a movement distance in the Y-axis direction when the measurement locations P1 to P3 are measured and the width of the gap 5. For example, the calculator 121 calculates each of coordinates (x, y) in the X-axis direction and the Y-axis direction for each of the measurement locations P1 to P3 under the assumption that the coordinates of the origin O are (0, 0), the movement distance in the Y-axis direction when measuring the measurement locations is referred to as a Y coordinate value y, and the width of the gap 5 is referred to as an X coordinate value x. Thereafter, the calculator 121 calculates an arc passing through the coordinates of the measurement locations P1 to P3, and calculates the central coordinates (x′, y′) of the center of the arc. For example, the calculator 121 performs circle fitting on the coordinates of the measurement locations P1 to P3, calculates a circle having the smallest error for the coordinates of the measurement locations P1 to P3, and calculates the central coordinates (x′, y′) of the center of the circle having the smallest error. For example, the calculator 121 calculates the center coordinates and radius of the circle having the smallest error for the coordinates of the measurement locations P1 to P3 by the least square method. Even if the diameter of the stage 2 differs for each stage 2, the calculator 121 may calculate the center coordinates and radius of the stage 2 by using the coordinates (x, y) of at least three measurement locations.

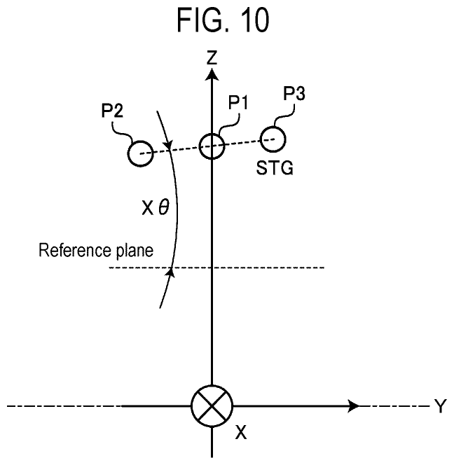

Further, the calculator 121 calculates the inclination of the stage 2 based on the heights of the stage 2 measured in the Z-axis direction at at least two locations. FIG. 10 is a view showing an example of calculating the inclination of the stage 2 according to the first embodiment. In FIG. 10, three measurement locations, at which the height H of the stage 2 in the Z-axis direction relative to the reference plane is measured, are indicated as measurement locations P1 to P3 on a plane in the vertical direction in the Y-axis direction and the Z-axis direction. The calculator 121 calculates the coordinates of the measurement locations P1 to P3 on the vertical plane based on the movement distance in the Y-axis direction and the height in the Z-axis direction when the measurement locations P1 to P3 are measured. For example, the calculator 121 calculates the coordinates (x, z) in the X-axis direction and the Z-axis direction on the vertical plane for each of the measurement locations P1 to P3, respectively, by setting the movement distance in the Y-axis direction when the measurement location is measured as a Y coordinate value y and setting the height H in the Z-axis direction as a Z coordinate value z. The calculator 121 calculates a straight line that passes through the coordinates of the measurement locations P1 to P3 with a smallest error. For example, the calculator 121 uses the least square method to calculate the straight line having the smallest error for the coordinates of the measurement locations P1 to P3. Thereafter, the calculator 121 calculates an angle of the straight line with respect to the Y-axis direction to calculate the rotational angle Xθ of the stage 2 about the X-axis direction as the rotation axis. The example in FIG. 10 shows a case where the rotational angle Xθ of the stage 2 is calculated based on the heights of the stage 2 in the Z-axis direction at three locations. The calculator 121 may calculate the rotational angle Xθ of the stage 2 by measuring the heights H of the stage 2 in the Z-axis direction at two or more locations.

The drive controller 122 controls the drive mechanism 7 based on the calculation results obtained by the calculator 121 to adjust at least one of the position or angle of the stage 2.

For example, the drive controller 122 adjusts a horizontal position of the stage 2 by the drive mechanism 7 so that the calculated central position of the stage 2 is located on the central axis of the cylindrical space in which the stage 2 may be placed at the processing position. For example, in the case of FIG. 9, the central axis of the cylindrical space passes through the center of the line L1 having the radius R. When the center of the line L1 having the radius R is located on the X axis, the central coordinate of the center of the line L1 having the radius R is (R, 0). The drive controller 122 moves the stage 2 in the X-axis direction and the Y-axis direction so that the calculated central coordinate (x′, y′) of the stage 2 becomes a coordinate (R, 0). For example, when R=10 and the central coordinate (x′, y′) of the stage 2 are (9, −2) in FIG. 9, the drive controller 122 moves the stage 2 by 1 (=10-9) in the X-axis direction and 2 (=0−(−2)) in the Y-axis direction by the drive mechanism 7. As a result, the central position of the stage 2 is located on the central axis of the cylindrical space in which the stage 2 may be placed. Therefore, the drive controller 122 may adjust the position of the stage 2 so that the width of the gap 5 becomes uniform.

Further, the drive controller 122 controls the drive mechanism 7 based on the measured height of the stage 2 in the Z-axis direction to adjust the height of the stage 2. For example, the drive controller 122 adjusts the height of the stage 2 so that the stage 2 is located at a predetermined height, based on the measured height of the stage 2 in the Z-axis direction at any location. For example, when the drive controller 122 measures heights of the stage 2 in the Z-axis direction at three measurement locations P1 to P3 as shown in FIG. 10, the drive controller 122 adjusts the height of the stage 2 so that the height in the Z-axis direction at the measurement location P1 becomes a predetermined height. Thus, the drive controller 122 may adjust the height of the stage 2 in the Z-axis direction to the predetermined height.

Further, the drive controller 122 controls the drive mechanism 7 based on the measured inclination of the stage 2 to adjust the inclination of the stage 2. For example, the drive controller 122 rotates the stage 2 about the Y-axis direction and the X-axis direction as the rotation axes, respectively, so that both the measured rotational angles Yθ and Xθ are zero degrees. For example, the drive controller 122 rotates the stage 2 about the rotation axis in the Y-axis direction so that the stage 2 may be rotated by −Yθ. Further, the drive controller 122 rotates the stage 2 about the rotation axis in the X-axis direction so that the stage 2 may be rotated by −Xθ. Thus, the drive controller 122 may horizontally adjust the inclination of the stage 2.

The drive controller 122 stores information about the position and inclination of the stage 2 at the adjusted processing position in the memory part 103 as processing position information 110. For example, the drive controller 122 stores, as the processing position information 110 in the memory part 103, a coordinate (x, y, z) of the stage 2 in the X-axis direction, the Y-axis direction, and the Z-axis direction at the adjusted processing position, and the rotational angles (xθ, yθ) about the X-axis direction and the Y-axis direction as the rotation axes.

The substrate processing apparatus 100 according to the embodiment performs teaching to adjust the position of the stage 2 during a period when the film formation process is not performed, such as during introduction or maintenance of the apparatus, and stores the information about the position and inclination of the stage 2 at the adjusted processing position in the memory part 103 as the processing position information 110. When raising the stage 2 to the processing position, the drive controller 122 controls the drive mechanism 7 to raise the stage 2 to the processing position based on the position and inclination included in the processing position information 110. As a result, when raising the stage 2 to the processing position, the substrate processing apparatus 100 may dispose the stage 2 so that the width of the gap 5 becomes uniform.

### Specific Example of Flow of Adjustment Process

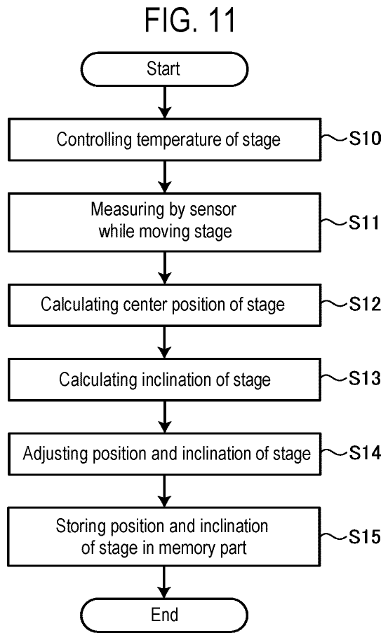

Next, a specific example of a flow of an adjustment process including the adjustment method according to the first embodiment will be described. FIG. 11 is a flowchart showing an example of the flow of the adjustment process according to the first embodiment.

The measurement controller 120 controls the temperature of the stage 2 to a target temperature for adjusting the position of the stage 2 (step S10). For example, when adjusting the position of the stage 2 in conformity with the film formation process, the measurement controller 120 causes the heater 2b to generate heat, and controls the temperature of the stage 2 to a predetermined temperature adapted for the film formation process.

The measurement controller 120 performs measurement using the sensor 6 while moving the stage 2 in the Y-axis direction (step S11). For example, the measurement controller 120 measures the widths of the gap 5 at at least three different locations on the stage 2 using the sensor 6 while moving the stage 2 in the Y-axis direction. Further, the measurement controller 120 measures the heights of the stage 2 in the Z-axis direction at at least two of at least three different locations at each of which the width of the gap 5 is measured. For example, the measurement controller 120 measures the height of the stage 2 in the Z-axis direction at each location where the width of the gap 5 is measured. Further, the measurement controller 120 measures the rotational angle Yθ of the stage 2 about the Y-axis direction as the rotation axis at at least one of at least three different locations in each of which the width of the gap 5 is measured.

The calculator 121 calculates the central position of the stage 2 based on the widths of the gaps 5 measured at at least three different locations (step S12).

The calculator 121 calculates the inclination of the stage 2 based on the heights of the stage 2 in the Z-axis direction measured at at least two locations (step S13). For example, the calculator 121 calculates the rotational angle Xθ of the stage 2 about the X-axis direction of the stage 2 as the rotation axis based on the heights of the stage 2 in the Z-axis direction measured at at least two locations.

The drive controller 122 controls the drive mechanism 7 based on the calculation results obtained by the calculator 121 to adjust the position and inclination of the stage 2 (step S14). For example, the drive controller 122 adjusts the horizontal position of the stage 2 by the drive mechanism 7 so that the calculated central position of the stage 2 is located on the central axis of the cylindrical space in which the stage 2 may be placed at the processing position. In addition, the drive controller 122 controls the drive mechanism 7 based on the measured height of the stage 2 in the Z-axis direction to adjust the height of the stage 2. In addition, the drive controller 122 controls the drive mechanism 7 based on the measured inclination of the stage 2 to adjust the inclination of the stage 2. For example, the drive controller 122 rotates the stage 2 about the rotation axis in the Y-axis direction and the rotation axis in the X-axis direction so that both the measured rotational angle Yθ and the measured rotational angle Xθ are zero degrees.

The drive controller 122 stores the information about the position and inclination of the stage 2 at the adjusted processing position in the memory part 103 as processing position information 110 (step S15), and ends the process.

Therefore, the substrate processing apparatus 100 according to the first embodiment may suppress the processing results of the film formation process in the circumferential direction of the stage 2 from becoming non-uniform.

In the adjustment process of the above-described embodiment, there has been described a case where the width of the gap 5 is measured at at least three different locations by the sensor 6 while moving the stage 2 in the Y-axis direction, and all three of the horizontal position, the height, and the inclination of the stage 2 are adjusted. However, the present disclosure is not limited thereto. For example, the adjustment process may adjust one or two of the horizontal position, the height, and the inclination of the stage 2. Further, the adjustment process may adjust the horizontal position, the height, and the inclination of the stage 2 as follows. In the adjustment process, the widths of the gap 5 are measured at at least three different locations by the sensor 6 while moving the stage 2 in the Y-axis direction, and the horizontal position, the height, and the rotational angle Yθ of the stage 2 about the Y-axis direction of the stage 2 as the rotation axis are measured. Further, the horizontal position of the stage 2 is adjusted so that the central position of the stage 2 is located on the central axis of the cylindrical space in which the stage 2 may be placed at the processing position. Subsequently, the rotational angle Yθ is adjusted to ensure the horizontal rotation of the stage 2 in the Y-axis direction. Subsequently, the height of the stage 2 in the Z-axis direction is adjusted. Thereafter, the sensor 6 performs measurements at two or more locations while moving the stage 2 in the Y-axis direction. The rotational angle Xθ about the X-axis direction of the stage 2 as the rotation axis is calculated based on the heights of the stage 2 in the Z-axis direction measured at at least two locations.

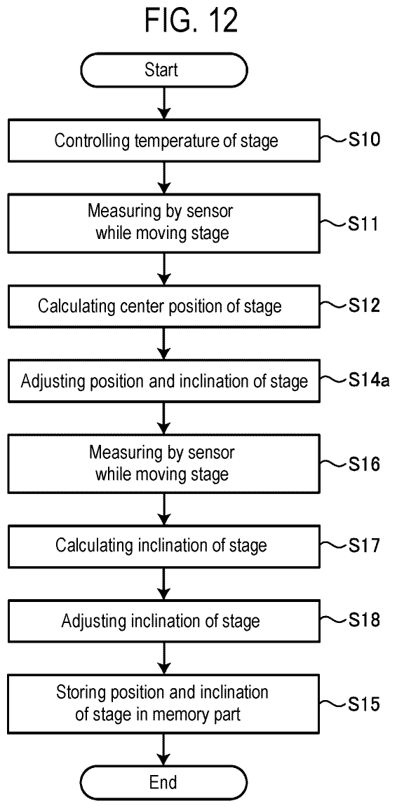

Then, the rotational angle Xθ is adjusted to ensure the horizontal rotation of the stage 2 in the X-axis direction. FIG. 12 is a flowchart showing another example of the flow of the adjustment process according to the first embodiment. The adjustment process shown in FIG. 12 is partially similar to the adjustment process shown in FIG. 11. Therefore, the same parts are designated by like reference numerals with the descriptions thereof omitted, and different parts will be mainly described. In step S14a, the drive controller 122 controls the drive mechanism 7 based on the calculation results obtained by the calculator 121 to adjust the position and inclination of the stage 2. For example, the drive controller 122 adjusts the horizontal position of the stage 2 by the drive mechanism 7 so that the calculated central position of the stage 2 is located on the central axis of the cylindrical space in which the stage 2 may be placed at the processing position. Further, the drive controller 122 controls the drive mechanism 7 based on the measured height of the stage 2 in the Z-axis direction to adjust the height of the stage 2. Further, the drive controller 122 controls the drive mechanism 7 based on the measured inclination of the stage 2 to adjust the inclination of the stage 2. For example, the drive controller 122 rotates the stage 2 about the rotation axis in the Y-axis direction so that the measured rotational angle Yθ becomes zero degrees. After step S14a, the measurement controller 120 measures the widths of the gap 5 at at least two different locations on the stage 2 using the sensor 6 while moving the stage 2 in the Y-axis direction (step S16). The calculator 121 calculates the rotational angle Xθ of the stage 2 about the X-axis direction as the rotation axis based on the heights of the stage 2 in the Z-axis direction measured at at least two locations (step S17). The drive controller 122 controls the drive mechanism 7 based on the measured inclination of the stage 2 to adjust the inclination of the stage 2. For example, the drive controller 122 rotates the stage 2 about the rotation axis in the X-axis direction so that the measured rotational angle Xθ becomes zero degrees. Even when the adjustment process shown in FIG. 12 has been performed, the substrate processing apparatus 100 according to the first embodiment may suppress the processing result of the film formation process in the circumferential direction of the stage 2 from becoming non-uniform.

In the above-described embodiment, there has been described a case where the sensor 6 is provided in the ceiling portion of the processing container 1 above the gap 5 in the interior of the processing container 1. However, the present disclosure is not limited thereto. The sensor 6 may be provided anywhere as long as it may measure the width of the gap 5 between the stage 2 and the processing container 1. For example, the sensor 6 may be provided below the gap 5 in the interior of the processing container 1. A thickness of the stage 2 may be calculated in advance from an actual measurement of the stage 2 or design data of the stage 2. For example, in a case in which the gap 5 is measured from below, a height of the upper surface side of the stage 2 may be measured by adding the thickness of the stage 2 calculated in advance to a height of the lower surface side of the stage 2. For example, the substrate processing apparatus 100 may be configured such that a transmission window is provided in a portion above the gap 5 in the ceiling portion of the processing container 1, and the sensor 6 is provided above the transmission window to measure the gap 5 from the outside of the processing container 1 via the transmission window. For example, the substrate processing apparatus 100 may be configured such that the sensor 6 is not provided in the processing container 1 and is disposed when the teaching is performed. For example, the substrate processing apparatus 100 may be configured such that the ceiling portion of the processing container 1 is replaced with a ceiling member provided with the sensor 6 to perform the teaching.

In the above-described embodiment, there has been described a case where the substrate processing apparatus 100 is an apparatus that performs the film forming process as the substrate processing. However, the present disclosure is not limited thereto. The substrate processing may be, for example, an etching process such as plasma etching, or any other substrate processing. The disclosed technique is applicable to any apparatus that performs other substrate processing such as plasma etching or the like.

### Effects of the First Embodiment

As described above, the substrate processing apparatus 100 according to the first embodiment includes the stage 2, the processing container 1, the drive mechanism (the drive mechanism 7 and the rotation mechanism 8), and the sensor 6. The stage 2 includes the circular placement surface on which the substrate W is placed. The processing container 1 includes the central axis extending in the vertical direction, and has the cylindrical internal space in which the stage 2 is disposed with the gap 5 provided between the processing container 1 and the stage 2. The drive mechanism is configured to be able to move the stage 2 at least in the horizontal direction. The sensor 6 is configured to be able to measure the width of the gap 5 in the X-axis direction (the first horizontal direction) that intersects the gap 5. The adjustment method used for the substrate processing apparatus 100 according to the first embodiment includes a first operation (steps S10 and S11), a second operation (steps S12 and S13), and a third operation (step S14). In the first operation, the sensor 6 measures the widths of the gap 5 at at least three different locations on the stage 2 while moving the stage 2 in the Y-axis direction (the second horizontal direction) perpendicular to the X-axis direction by the drive mechanism. In the second operation (step S12), the central position of the stage 2 is calculated based on the widths of the gap 5 measured at at least three different locations. In third operation, the drive mechanism adjusts the horizontal position of the stage 2 so that the calculated central position of the stage 2 is located on the central axis. Therefore, the adjustment method used for the substrate processing apparatus 100 according to the first embodiment may adjust the position of the stage 2 so that the width of the gap 5 becomes uniform.

Further, the sensor 6 is a two-dimensional sensor that measures the shapes of the gap 5 and the peripheral edge of the stage 2 in the X-axis direction. In the first operation, the sensor 6 measures the shapes at at least three different locations on the stage 2 while moving the stage 2 in the Y-axis direction by the drive mechanism, and measures the widths of the gap 5 at at least three different locations based on individual shapes. Therefore, the adjustment method used for the substrate processing apparatus 100 according to the first embodiment may measure the width of the gap 5 by the sensor 6 configured to measure the shapes.

Further, the drive mechanism is configured to be able to change the inclination of the stage 2 with respect to the vertical direction. That is, the drive mechanism is configured to be able to displace the stage 2 about the X-axis. In the first operation, the vertical height of the peripheral edge of the stage 2 is measured based on the shapes of the peripheral edge of the stage 2 measured at at least two locations. In the second operation (step S13), the rotational angle Xθ (the first rotational angle) of the stage 2 about the X-axis direction as the rotation axis is calculated based on the heights measured at at least two locations. In the third operation, the drive mechanism adjusts the angle of the stage 2 about the X-axis direction as the rotation axis based on the calculated rotational angle Xθ. Therefore, the adjustment method used for the substrate processing apparatus 100 according to the first embodiment may adjust the angle of the stage 2 about the X-axis direction as the rotation axis. For example, the inclination of the stage 2 may be adjusted so that the rotational angle Xθ becomes zero degrees.

Further, the drive mechanism is configured to be able to change the inclination of the stage 2 with respect to the vertical direction. That is, the drive mechanism is configured to be able to displace the stage 2 about the Y-axis. In the first operation, the rotational angle Yθ (the second rotational angle) of the stage 2 about the Y-axis direction as the rotation axis is measured based on the shapes of the peripheral edge of the stage 2. In the third operation, the angle of the stage 2 about the Y-axis direction as the rotation axis is adjusted by the drive mechanism based on the rotational angle Yθ. Therefore, the adjustment method used for the substrate processing apparatus 100 according to the first embodiment may adjust the angle of the stage 2 about the Y-axis direction as the rotation axis. For example, the inclination of the stage 2 may be adjusted so that the rotational angle Yθ becomes zero degrees.

Further, the drive mechanism is configured to be able to further move the stage 2 in the vertical direction. In the first operation, the vertical height of the stage 2 at at least one point is measured based on the shape of the peripheral edge of the stage 2. In the third operation, the drive mechanism adjusts the vertical position of the stage 2 based on the measured height. Therefore, the adjustment method used for the substrate processing apparatus 100 according to the first embodiment may adjust the height of the stage 2. For example, the height of the stage 2 may be adjusted to a predetermined height.

Further, the drive mechanism is configured to change the inclination of the stage 2 with respect to the vertical direction and to move the stage 2 in the vertical direction. In the first operation, the rotational angle Yθ of the stage 2 about the Y-axis direction as the rotation axis is measured based on the shape of the peripheral edge of the stage 2, and the vertical height is measured based on the shape of the peripheral edge of the stage 2 at at least one point on the stage 2. In the third operation (step S14a), the drive mechanism adjusts the angle of the stage 2 about the Y-axis direction as the rotation axis based on the rotational angle Yθ, and adjusts the vertical position of the stage 2 by the drive mechanism based on the measured height. The adjustment method used for the substrate processing apparatus 100 according to the first embodiment further includes a fourth operation (step S16), a fifth operation (step S17), and a sixth operation (step S18). In the fourth operation, after the third operation, while moving the stage 2 in the Y-axis direction by the drive mechanism, the sensor measures the vertical height of the peripheral edge of the stage 2 from the shapes of the peripheral edge of the stage 2 at at least two locations on the stage 2. In the fifth operation, the rotational angle Xθ of the stage 2 about the X-axis direction as the rotation axis is calculated from the heights measured at at least two locations. In the sixth operation, the angle of the stage 2 about the X-axis direction as the rotation axis is adjusted by the drive mechanism based on the calculated rotational angle Xθ. Therefore, the adjustment method used for the substrate processing apparatus 100 according to the first embodiment may adjust the position of the stage 2, the angle of the stage 2, and the height of the stage 2. For example, the inclination of the stage 2 may be adjusted so that both the rotational angle Xθ and the rotational angle Yθ become zero degrees. In addition, the height of the stage 2 may be adjusted to a predetermined height.

Further, the stage 2 is configured such that a temperature thereof may be controlled. In the first operation (steps S10 and S11), the temperature of the stage 2 is controlled to a temperature adapted for the substrate processing on the substrate W, and the width of the gap 5 is measured. Therefore, the adjustment method used for the substrate processing apparatus 100 according to the first embodiment may adjust the position of the stage 2 so that the width of the gap 5 becomes uniform at the temperature during the substrate processing.

Further, in the first operation, in the case in which the width of the gap 5 is measured by the sensor 6 after moving the stage 2 to one side in the Y-axis direction, when the width of the gap 5 gradually increases, the stage 2 is moved to the other side in the Y-axis direction and the width of the gap 5 is measured by the sensor 6. Therefore, the adjustment method used for the substrate processing apparatus 100 according to the first embodiment may prevent the stage 2 from being brought into contact with the component member 4 or the inner surface of the processing container 1 when the gap 5 is measured while moving stage 2 in the Y-axis direction.

Further, when the stage 2 is raised to the processing position where the substrate W is processed, the internal space in which the stage 2 is disposed is formed in the processing container 1 with the gap 5 provided between the inner wall of the processing container 1 or the component member 4 provided on the inner wall and the side surface of the stage 2. The sensor 6 is configured to be able to measure the width of the gap 5 between the stage 2 and the inner wall or the component member 4. Thus, the adjustment method used for the substrate processing apparatus 100 according to the first embodiment may adjust the position of the stage 2 so that the width of the gap 5 between the stage 2 and the inner wall or the component member 4 becomes uniform at the processing position where the substrate W is processed.

### Second Embodiment

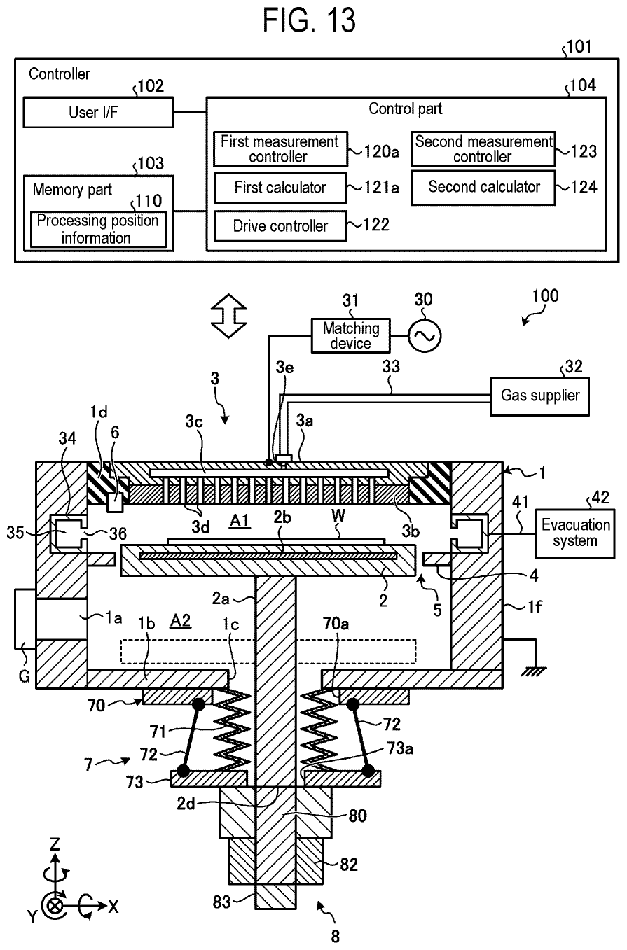

Next, an example of a schematic configuration of a substrate processing apparatus 100 according to a second embodiment will be described. FIG. 13 is a schematic cross-sectional view showing an example of the configuration of the substrate processing apparatus 100 according to the second embodiment. The substrate processing apparatus 100 according to the second embodiment is partially similar in configuration to the substrate processing apparatus 100 according to the first embodiment. Therefore, the same parts will be designated by like reference numerals with descriptions thereof omitted, and different parts will be mainly described.

The control part 104 includes functions of a first measurement controller 120a, a first calculator 121a, a drive controller 122, a second measurement controller 123, and a second calculator 124.

The first measurement controller 120a includes some of the same functions as the measurement controller 120 according to the first embodiment. The first measurement controller 120a controls the temperature of the stage 2 to a target temperature for adjusting the position of the stage 2. For example, when adjusting the position of the stage 2 in conformity with the film formation process, the first measurement controller 120a controls a heater power supply (not shown) connected to the heater 2b to supply power to the heater 2b so that the heater 2b generates heat, and controls the temperature of the stage 2 to a temperature adapted for the film formation process.

The first measurement controller 120a controls the sensor 6 and the drive mechanism 7 to measure the widths of the gap 5 at at least three different locations on the stage 2 while moving the stage 2 in the Y-axis direction. The first measurement controller 120a measures the widths of the gap 5 from the shapes measured by the sensor 6.

The first calculator 121a includes some of the same functions as the calculator 121 according to the first embodiment. The first calculator 121a calculates the center coordinate and radius of the stage 2 from the widths of the gaps 5 measured at at least three different locations.

The second measurement controller 123 controls the rotation mechanism 8 to rotate the stage 2. The second measurement controller 123 measures the stage 2 using the sensor 6 while rotating the stage 2 using the rotation mechanism 8. For example, the second measurement controller 123 measures the rotating stage 2 at a predetermined period using the sensor 6 while rotating the stage 2 at least once in the circumferential direction using the rotation mechanism 8. The second measurement controller 123 measures the change in height of the stage 2 from the shape of the peripheral edge of the stage 2 measured by the sensor 6. For example, the second measurement controller 123 measures the change in height of the stage 2 from the shape of the peripheral edge of the stage 2 measured at the predetermined period.

In this case, when the stage 2 is rotated in a tilted state, the height of the peripheral edge is changed.

The second calculator 124 calculates the inclination of the upper surface of the stage 2 from the measured change in height of the stage 2. For example, the second calculator 124 specifies a direction in which the upper surface of the stage 2 is tilted from rotational angles at the highest position and the lowest position with respect to the circumferential direction of the stage 2. Further, the second calculator 124 calculates a degree of change in height of the stage 2 from a height difference between the highest position and the lowest position, and calculates an angle at which the height change occurs in a diameter twice the radius of the stage 2. The second calculator 124 divides the inclination of the upper surface of the stage 2 into rotation-axis components in the X-axis direction and Y-axis direction to calculate the rotational angle Xθ and the rotational angle Yθ.

The drive controller 122 controls the drive mechanism 7 based on the calculation results obtained by the first measurement controller 120a and the second calculator 124 to adjust at least one of the position or angle of the stage 2.

For example, the drive controller 122 adjusts the horizontal position of the stage 2 using the drive mechanism 7 so that the central position of the stage 2 calculated by the first calculator 121a is located on the central axis of the cylindrical space in which the stage 2 may be placed at the processing position.

Further, the drive controller 122 controls the drive mechanism 7 to adjust the height of the stage 2 based on the height of the stage 2 in the Z-axis direction measured by the second measurement controller 123. For example, the drive controller 122 adjusts the height of the stage 2 so that the stage 2 is at a predetermined height based on the height of the stage 2 in the Z-axis direction at any location, which is measured by the second measurement controller 123. In addition, for example, the drive controller 122 adjusts the height of the stage 2 so that the height at an intermediate position between the highest position and the lowest position in the circumferential direction becomes a predetermined height. Thus, the drive controller 122 may adjust the height of the stage 2 in the Z-axis direction to the predetermined height.

Further, the drive controller 122 controls the drive mechanism 7 based on the inclination of the stage 2 to adjust the inclination of the stage 2. For example, the drive controller 122 rotates the stage 2 about the Y-axis direction and the X-axis direction as the rotation axes so that both rotational angles Yθ and Xθ calculated by the second calculator 124 become zero degrees. For example, the drive controller 122 rotates the stage 2 about the Y-axis direction as the rotation axis so that the stage 2 is rotated by −Yθ. Further, the drive controller 122 rotates the stage 2 about the X-axis direction as the rotation axis so that the stage 2 is rotated by −Xθ. Thus, the drive controller 122 may adjust the inclination of the stage 2 horizontally.

### Specific Example of Flow of Adjustment Process

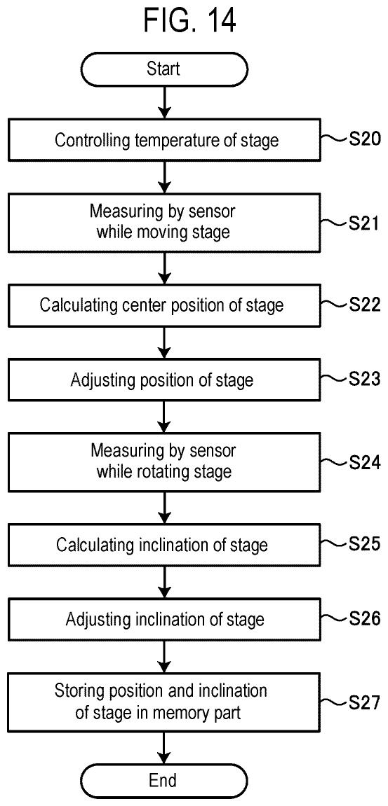

Next, a specific example of the flow of the adjustment process including the adjustment method according to the second embodiment will be described. FIG. 14 is a flowchart showing an example of the flow of the adjustment process according to the second embodiment.

The first measurement controller 120a controls the temperature of the stage 2 to a target temperature for adjusting the position of the stage 2 (step S20). For example, when adjusting the position of the stage 2 in conformity with the film formation process, the first measurement controller 120a causes the heater 2b to generate heat, and controls the temperature of the stage 2 to a predetermined temperature adapted for the film formation process.

The first measurement controller 120a performs measurement using the sensor 6 while moving the stage 2 in the Y-axis direction (step S21). For example, the first measurement controller 120a measures the widths of the gap 5 at at least three different locations on the stage 2 using the sensor 6 while moving the stage 2 in the Y-axis direction.

The first calculator 121a calculates the central position of the stage 2 from the widths of the gaps 5 measured at at least three different locations (step S22).

Based on the calculation results obtained by the first measurement controller 120a, the drive controller 122 controls the drive mechanism 7 to adjust the position of the stage 2 (step S23). For example, the drive controller 122 adjusts the horizontal position of the stage 2 by the drive mechanism 7 so that the central position of the stage 2 calculated by the first calculator 121a is located on the central axis of the cylindrical space in which the stage 2 may be placed at the processing position.

The second measurement controller 123 measures the height of the stage 2 by the sensor 6 while rotating the stage 2 by the rotation mechanism 8 (step S24). For example, the second measurement controller 123 measures the height of the rotating stage 2 by the sensor 6 at a predetermined period while rotating the stage 2 at least once in the circumferential direction by the rotation mechanism 8.

The second calculator 124 calculates the inclination of the upper surface of the stage 2 from the measured change in height of the stage 2 (step S25). The second calculator 124 divides the inclination of the upper surface of the stage 2 into rotation-axis components in the X-axis direction and the Y-axis direction, and calculates the rotational angle Xθ and the rotational angle Yθ.

The drive controller 122 controls the drive mechanism 7 based on the calculation results obtained by the second calculator 124 to adjust the inclination of the stage 2 (step S26). For example, the drive controller 122 controls the drive mechanism 7 based on the height of the stage 2 in the Z-axis direction measured by the second measurement controller 123 to adjust the height of the stage 2. Further, the drive controller 122 controls the drive mechanism 7 based on the inclination of the stage 2 calculated by the second calculator 124 to adjust the inclination of the stage 2. For example, the drive controller 122 rotates the stage 2 about the rotation axis in the Y-axis direction and the rotation axis in the X-axis direction so that both the measured rotational angles Yθ and Xθ calculated by the second calculator 124 become zero degrees.

The drive controller 122 stores the position and inclination of the stage 2 at the adjusted processing position in the memory part 103 as the processing position information 110 (step S27), and ends the process.

Accordingly, the substrate processing apparatus 100 according to the second embodiment may suppress the processing results of the film formation process in the circumferential direction of the stage 2 from becoming non-uniform.

In the above-described embodiment, there has been described a case where the position of the stage 2 is adjusted (step S23), and then the inclination and height of the stage 2 are adjusted (step S26). However, the present disclosure is not limited thereto. For example, the adjustment of the height, inclination and height of the stage 2 may be performed in step S26.

### Effects of the Second Embodiment

As described above, the drive mechanism is configured to rotate the stage 2 and further change the inclination of the stage 2 in the vertical direction. The adjustment method used for the substrate processing apparatus 100 according to the second embodiment includes a seventh operation (step S24), an eighth operation (step S25), and a ninth operation (step S26). In the seventh operation, the sensor 6 measures the shape of the peripheral edge of the stage 2 while rotating the stage 2 by the drive mechanism, and measures a change in height of the stage 2 from the shape of the peripheral edge of the stage 2. In the eighth operation, the inclination of the upper surface of the stage 2 is calculated from the measured change in height. In the ninth operation, the drive mechanism adjusts the inclination of the stage 2 based on the calculated inclination of the upper surface of the stage 2. As a result, the adjustment method used for the substrate processing apparatus 100 according to the second embodiment may adjust the inclination of the stage 2. For example, the inclination of the stage 2 may be adjusted so that both the rotational angle Xθ and the rotational angle Yθ become zero degrees.

According to the present disclosure in some embodiments, it is possible to adjust a position of a stage so that a width of a gap becomes uniform.

The disclosed embodiments should be considered to be exemplary and not limitative in all respects. Indeed, the above-described embodiments may be embodied in various forms. In addition, the above-described embodiments may be omitted, substituted, or modified in various forms without departing from the scope and spirit of the appended claims.

The following supplementary notes are further provided for the above-described embodiments.

### (Supplementary Note 1)

An adjustment method used for a substrate processing apparatus provided with: a stage having a circular placement surface on which a substrate is placed; a processing container having a central axis extending in a vertical direction and a cylindrical interior space in which the stage is disposed with a gap provided around the stage; a drive mechanism configured to move the stage at least in a horizontal direction; and a sensor configured to measure a width of the gap in a first horizontal direction intersecting the gap, includes: a first operation of measuring widths of the gap at at least three different locations on the stage by the sensor while moving the stage in a second horizontal direction perpendicular to the first horizontal direction by the drive mechanism; a second operation of calculating a central position of the stage based on the widths of the gap measured at the at least three different locations; and a third operation of adjusting a horizontal position of the stage by the drive mechanism so that the calculated central position of the stage is located on the central axis.

### (Supplementary Note 2)

In the adjustment method of Supplementary Note 1 above, the sensor is a two-dimensional sensor configured to measure the gap and a shape of a peripheral edge of the stage in the first horizontal direction, and the first operation includes measuring shapes of the peripheral edge of the stage at the at least three different locations by the sensor while moving the stage in the second horizontal direction by the drive mechanism, and measuring the widths of the gap at the at least three different locations based on the shapes.

### (Supplementary Note 3)

In the adjustment method of Supplementary Note 2 above, the drive mechanism is further configured to change an inclination of the stage with respect to the vertical direction, the first operation includes measuring vertical heights of the peripheral edge of the stage based on the shapes of the peripheral edge of the stage at at least two locations on the stage, the second operation includes calculating a first rotational angle of the stage about the first horizontal direction as a rotation axis based on the vertical heights measured at the at least two locations, and the third operation includes adjusting an angle of the stage about the first horizontal direction as the rotation axis by the drive mechanism based on the first rotational angle.

### (Supplementary Note 4)

In the adjustment method of Supplementary Note 2 or 3 above, the drive mechanism is further configured to change an inclination of the stage with respect to the vertical direction, the first operation includes measuring a second rotational angle of the stage about the second horizontal direction as a rotation axis based on the shapes of the peripheral edge of the stage, and the third operation includes adjusting an angle of the stage about the second horizontal direction as the rotation axis by the drive mechanism based on the second rotational angle.

### (Supplementary Note 5)

In the adjustment method of any one of Supplementary Notes 2 to 4 above, the drive mechanism is further configured to move the stage in the vertical direction, the first operation includes measuring a vertical height of the stage based on the shape of the peripheral edge of the stage at at least one point on the stage, and the third operation includes adjusting a vertical position of the stage by the drive mechanism based on the vertical height.

### (Supplementary Note 6)

In the adjustment method of Supplementary Note 2 above, the drive mechanism is further configured to change an inclination of the stage with respect to the vertical direction and to move the stage in the vertical direction, wherein the first operation includes measuring a second rotational angle of the stage about the second horizontal direction as a rotation axis based on the shape of the peripheral edge of the stage, and measuring a vertical height of the stage based on the shape of the peripheral edge of the stage at at least one point on the stage, and the third operation includes adjusting an angle of the stage about the second horizontal direction as the rotation axis by the drive mechanism based on the second rotational angle, and adjusting a vertical position of the stage by the drive mechanism based on the vertical height. The adjustment method further includes: after the third operation, a fourth operation of measuring, by the sensor, vertical heights of the peripheral edge of the stage based on the shapes of the peripheral edge of the stage at at least two locations on the stage while moving the stage in the second horizontal direction by the drive mechanism; a fifth operation of calculating a first rotational angle of the stage about the first horizontal direction as a rotation axis based on the vertical heights measured at the at least two locations; and a sixth operation of adjusting an angle of the stage about the first horizontal direction as the rotation axis by the drive mechanism based on the first rotational angle.

### (Supplementary Note 7)

In the adjustment method of Claim 2, the drive mechanism is further configured to rotate the stage and change an inclination of the stage with respect to the vertical direction. The adjustment method further includes: a seventh operation of measuring the shape of the peripheral edge of the stage by the sensor while rotating the stage by the drive mechanism, and measuring a change in height of the stage from the shape of the peripheral edge of the stage; an eighth operation of calculating an inclination of an upper surface of the stage based on the change in height; and a ninth operation of adjusting the inclination of the stage by the drive mechanism based on the inclination of the upper surface of the stage.

### (Supplementary Note 8)

In the adjustment method of any one of Supplementary Notes 1 to 7 above, the stage is configured such that a temperature thereof is capable of being controlled, and the first operation includes measuring the width of the gap while controlling the temperature of the stage to a temperature during substrate processing on the substrate.

### (Supplementary Note 9)

In the adjustment method of any one of Supplementary Notes 1 to 8 above, in the first operation, in a case of measuring the width of the gap by the sensor while moving the stage to a first side in the second horizontal direction, when the width of the gap becomes gradually wider, the width of the gap is measured by the sensor while moving the stage to a second side in the second horizontal direction.

### (Supplementary Note 10)

In the adjustment method of any one of Supplementary Notes 1 to 9 above, when the stage is raised to a processing position where the substrate is processed, the cylindrical interior space of the processing container in which the stage is disposed is formed with the gap provided between an inner wall of the processing container or a component member provided on the inner wall and a side surface of the stage, and the sensor is configured to measure the width of the gap between the stage and the inner wall or the component member.

### (Supplementary Note 11)

A substrate processing apparatus includes: a stage having a circular placement surface on which a substrate is placed; a processing container having a central axis extending in a vertical direction and a cylindrical interior space in which the stage is disposed with a gap provided around the stage; a drive mechanism configured to move the stage at least in a horizontal direction; a sensor configured to measure a width of the gap in a first horizontal direction intersecting the gap; a measurement controller configured to perform a control to measure widths of the gap at at least three different locations on the stage by the sensor while moving the stage in a second horizontal direction perpendicular to the first horizontal direction by the drive mechanism; a calculator configured to calculate a central position of the stage based on the widths of the gap measured at the at least three different locations; and an adjuster configured to adjust a horizontal position of the stage by the drive mechanism so that the central position of the stage is located on the central axis.

What is claimed is:

1. An adjustment method used for a substrate processing apparatus,
wherein the substrate processing apparatus includes:
a stage having a circular placement surface on which a substrate is placed;
a processing container having a central axis extending in a vertical direction and a cylindrical interior space in which the stage is disposed with a gap provided around the stage;
a drive mechanism configured to move the stage at least in a horizontal direction; and
a sensor configured to measure a width of the gap in a first horizontal direction intersecting the gap,
the adjustment method comprising:
a first operation of measuring widths of the gap at at least three different locations on the stage by the sensor while moving the stage in a second horizontal direction perpendicular to the first horizontal direction by the drive mechanism;
a second operation of calculating a central position of the stage based on the widths of the gap measured at the at least three different locations; and
a third operation of adjusting a horizontal position of the stage by the drive mechanism so that the calculated central position of the stage is located on the central axis.

2. The adjustment method of claim 1, wherein the sensor is a two-dimensional sensor configured to measure the gap and a shape of a peripheral edge of the stage in the first horizontal direction, and
wherein the first operation includes measuring shapes of the peripheral edge of the stage at the at least three different locations by the sensor while moving the stage in the second horizontal direction by the drive mechanism, and measuring the widths of the gap at the at least three different locations based on the shapes.

3. The adjustment method of claim 2, wherein the drive mechanism is further configured to change an inclination of the stage with respect to the vertical direction,
wherein the first operation includes measuring vertical heights of the peripheral edge of the stage based on the shapes of the peripheral edge of the stage at at least two locations on the stage,
wherein the second operation includes calculating a first rotational angle of the stage about the first horizontal direction as a rotation axis based on the vertical heights measured at the at least two locations, and
wherein the third operation includes adjusting an angle of the stage about the first horizontal direction as the rotation axis by the drive mechanism based on the first rotational angle.

4. The adjustment method of claim 2, wherein the drive mechanism is further configured to change an inclination of the stage with respect to the vertical direction,
wherein the first operation includes measuring a second rotational angle of the stage about the second horizontal direction as a rotation axis based on the shapes of the peripheral edge of the stage, and
wherein the third operation includes adjusting an angle of the stage about the second horizontal direction as the rotation axis by the drive mechanism based on the second rotational angle.

5. The adjustment method of claim 2, wherein the drive mechanism is further configured to move the stage in the vertical direction,
wherein the first operation includes measuring a vertical height of the stage based on the shape of the peripheral edge of the stage at at least one point on the stage, and
wherein the third operation includes adjusting a vertical position of the stage by the drive mechanism based on the vertical height.

6. The adjustment method of claim 2, wherein the drive mechanism is further configured to change an inclination of the stage with respect to the vertical direction and to move the stage in the vertical direction,
wherein the first operation includes measuring a second rotational angle of the stage about the second horizontal direction as a rotation axis based on the shape of the peripheral edge of the stage, and measuring a vertical height of the stage based on the shape of the peripheral edge of the stage at at least one point on the stage,
wherein the third operation includes adjusting an angle of the stage about the second horizontal direction as the rotation axis by the drive mechanism based on the second rotational angle, and adjusting a vertical position of the stage by the drive mechanism based on the vertical height, and
wherein the adjustment method further comprises:
after the third operation, a fourth operation of measuring, by the sensor, vertical heights of the peripheral edge of the stage based on the shapes of the peripheral edge of the stage at at least two locations on the stage while moving the stage in the second horizontal direction by the drive mechanism;
a fifth operation of calculating a first rotational angle of the stage about the first horizontal direction as a rotation axis based on the vertical heights measured at the at least two locations; and
a sixth operation of adjusting an angle of the stage about the first horizontal direction as the rotation axis by the drive mechanism based on the first rotational angle.

7. The adjustment method of claim 2, wherein the drive mechanism is further configured to rotate the stage and change an inclination of the stage with respect to the vertical direction, and
wherein the adjustment method further comprises:
a seventh operation of measuring the shape of the peripheral edge of the stage by the sensor while rotating the stage by the drive mechanism, and measuring a change in height of the stage from the shape of the peripheral edge of the stage;
an eighth operation of calculating an inclination of an upper surface of the stage based on the change in height; and
a ninth operation of adjusting the inclination of the stage by the drive mechanism based on the inclination of the upper surface of the stage.

8. The adjustment method of claim 1, wherein the stage is configured such that a temperature thereof is capable of being controlled, and
wherein the first operation includes measuring the width of the gap while controlling the temperature of the stage to a temperature during substrate processing on the substrate.

9. The adjustment method of claim 1, wherein in the first operation, in a case of measuring the width of the gap by the sensor while moving the stage to a first side in the second horizontal direction, when the width of the gap becomes gradually wider, the width of the gap is measured by the sensor while moving the stage to a second side in the second horizontal direction.

10. The adjustment method of claim 1, wherein, when the stage is raised to a processing position where the substrate is processed, the cylindrical interior space of the processing container in which the stage is disposed is formed with the gap provided between an inner wall of the processing container or a component member provided on the inner wall and a side surface of the stage, and
wherein the sensor is configured to measure the width of the gap between the stage and the inner wall or the component member.

11. A substrate processing apparatus, comprising:
a stage having a circular placement surface on which a substrate is placed;
a processing container having a central axis extending in a vertical direction and a cylindrical interior space in which the stage is disposed with a gap provided around the stage;
a drive mechanism configured to move the stage at least in a horizontal direction;
a sensor configured to measure a width of the gap in a first horizontal direction intersecting the gap;
a measurement controller configured to perform a control to measure widths of the gap at at least three different locations on the stage by the sensor while moving the stage in a second horizontal direction perpendicular to the first horizontal direction by the drive mechanism;
a calculator configured to calculate a central position of the stage based on the widths of the gap measured at the at least three different locations; and
an adjuster configured to adjust a horizontal position of the stage by the drive mechanism so that the central position of the stage is located on the central axis.
